(19) United States
(12) Patent Application Publication
(10) Pub. No.: US 2025/0174599 A1
(43) Pub. Date: May 29, 2025

(54) SEMICONDUCTOR PACKAGE AND SEMICONDUCTOR PACKAGE MANUFACTURING METHOD

(71) Applicant: SAMSUNG ELECTRONICS CO., LTD., Suwon-si (KR)

(72) Inventors: Jihoon JUNG, Suwon-si (KR); IIhwan KIM, Suwon-si (KR); Unbyoung KANG, Suwon-si (KR); Yeongkwon KO, Suwon-si (KR)

(73) Assignee: SAMSUNG ELECTRONICS CO., LTD., Suwon-si (KR)

(21) Appl. No.: 18/744,103

(22) Filed: Jun. 14, 2024

(30) Foreign Application Priority Data
Nov. 29, 2023 (KR) 10-2023-0169622

(51) Int. Cl. H01L 25/065; H01L 23/00; H01L 23/48; H01L 23/498; H10B 80/00

(52) U.S. Cl. CPC H01L 25/0657; H01L 23/481; H01L 23/562; H01L 24/06; H01L 24/08; H01L 24/80; H01L 23/49816; H01L 24/05; H01L 2224/05647; H01L 2224/80379; H01L 2224/80895; H01L 2224/80896; H10B 80/00

(57) ABSTRACT

A semiconductor package includes a plurality of semiconductor chips each including a front insulating layer and a rear insulating layer, wherein the plurality of semiconductor chips are bonded to each other through a first direct bonding between the front insulating layer and the rear insulating layer, wherein at least one of the plurality of semiconductor chips includes: a device layer includes a wiring structure, a semiconductor substrate above the device layer, a plurality of front pads electrically connected to the wiring structure in front of the device layer, and the front insulating layer surrounding the plurality of front pads in front of the device layer, and wherein the front insulating layer includes a burr buried in an edge of a front surface of the front insulating layer.

### CROSS-REFERENCE TO RELATED APPLICATION

This application is based on and claims benefit of priority under 35 U.S.C. § 119 to Korean Patent Application No. 10-2023-0169622, filed on Nov. 29, 2023, in the Korean Intellectual Property Office, the disclosure of which is incorporated herein by reference in its entirety.

### BACKGROUND

### 1. Field

The disclosure relates to a semiconductor package and a manufacturing method of the semiconductor package.

### 2. Description of Related Art

According to the trend for miniaturization and high performance in a semiconductor package, there is a need for the development of system-in-package (SiP) technology that embeds a plurality of semiconductor chips performing different functions in a single package. In order to form fine wiring for connecting semiconductor chips in a package, a technology for forming a through-via (TSV) and bonding the semiconductor chips to each other with a bonding pad has been used.

### SUMMARY

Provided is a semiconductor package having improved electrical characteristics and/or reliability of a front surface of a semiconductor chip and a manufacturing method of the semiconductor package.

According to an aspect of the disclosure, a semiconductor package includes a plurality of semiconductor chips each including a front insulating layer and a rear insulating layer, wherein the plurality of semiconductor chips are bonded to each other through a first direct bonding between the front insulating layer and the rear insulating layer, wherein at least one of the plurality of semiconductor chips includes: a device layer includes a wiring structure, a semiconductor substrate above the device layer, a plurality of front pads electrically connected to the wiring structure in front of the device layer, and the front insulating layer surrounding the plurality of front pads in front of the device layer, and wherein the front insulating layer includes a burr buried in an edge of a front surface of the front insulating layer.

According to an aspect of the disclosure, a semiconductor package includes: a semiconductor chip including: a front insulating layer; a plurality of front pads surrounded by the front insulating layer; a device layer including a wiring structure electrically connected to the plurality of front pads and above the front insulating layer; a semiconductor substrate above the device layer; a through-via penetrating through the semiconductor substrate; and a rear insulating layer above the semiconductor substrate, wherein the front insulating layer has a step portion formed in an edge of a front surface of the front insulating layer, and wherein the front insulating layer includes a burr in the step portion so as to overlap a portion of the front insulating layer in a front-rear direction.

According to an aspect of the disclosure, a semiconductor package manufacturing method includes: forming a mask layer in front of a wafer including a semiconductor substrate, a device layer in front of the semiconductor substrate, and a front insulating layer in front of the device layer; forming a step portion in an edge of a front surface of the front insulating layer by removing a portion of the front insulating layer that does not overlap the mask layer in a front-rear direction along a scribe lane region of the wafer; removing a portion of the device layer and another portion of the front insulating layer having a width narrower than a width of a portion of the front insulating layer along the scribe lane region; removing a portion of the semiconductor substrate along the scribe lane region; and removing the mask layer.

### BRIEF DESCRIPTION OF DRAWINGS

The above and other aspects, features, and advantages of the disclosure will be more clearly understood from the following detailed description, taken in conjunction with the accompanying drawings, in which:

FIG. 1 is a cross-sectional view of a semiconductor package according to an example embodiment of the disclosure;

FIG. 2A is an enlarged view illustrating a portion A of the semiconductor package of FIG. 1;

FIG. 2B is an enlarged view illustrating a portion B of the semiconductor package of FIG. 1;

FIG. 2C is a plan view showing an X-Y cross-section taken along line I to I′ of the semiconductor package of FIG. 1;

FIGS. 3A to 3C are cross-sectional views illustrating various shapes of a burr of a semiconductor package according to an example embodiment of the disclosure;

FIGS. 4A and 4B are cross-sectional views illustrating various structures of direct bonding of a semiconductor package according to an example embodiment of the disclosure;

FIGS. 5A to 5G are cross-sectional views illustrating a semiconductor package manufacturing method according to an example embodiment of the disclosure before dicing a wafer;

FIGS. 6A and 6B are plan views illustrating a semiconductor package manufacturing method according to an example embodiment of the disclosure;

FIGS. 7A to 7F are cross-sectional views illustrating a semiconductor package manufacturing method according to an example embodiment of the disclosure;

FIG. 8 is a graph illustrating a femtosecond laser that may be used in a semiconductor package manufacturing method according to an example embodiment of the disclosure; and

FIGS. 9A to 9D are cross-sectional views illustrating a state after dicing a wafer in a semiconductor package manufacturing method according to an example embodiment of the disclosure.

### DETAILED DESCRIPTION

In the following detailed description of the disclosure, references are made to the accompanying drawings that show, by way of illustration, specific embodiments in which the disclosure may be practiced. These example embodiments are described in sufficient detail to enable those skilled in the art to implement the disclosure. It should be understood that various embodiments of the disclosure, although different, are not necessarily mutually exclusive. For example, specific features, structures, and characteristics described herein, in connection with one example embodiment, may be implemented within other embodiments without departing from the spirit and scope of the disclosure. In addition, it should be understood that the location or arrangement of individual elements within each disclosed embodiment may be modified without departing from the spirit and scope of the disclosure. The following detailed description is, therefore, not to be taken in a limiting sense, and the scope of the disclosure is defined only by the appended claims, appropriately interpreted, along with the full range of equivalents to what the claims claim. The similar reference numerals in the drawings refer to the same or similar functions in various aspects.

The terms “include” and “comprise”, and the derivatives thereof refer to inclusion without limitation. The term “or” is an inclusive term meaning “and/or”. The phrase “associated with,” as well as derivatives thereof, refer to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” refers to any device, system, or part thereof that controls at least one operation. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations thereof. As an additional example, the expression “at least one of a, b, or c” may indicate only a, only b, only c, both a and b, both a and c, both b and c, all of a, b, and c, or variations thereof. Similarly, the term “set” means one or more. Accordingly, the set of items may be a single item or a collection of two or more items.

In addition, in the disclosure, in order to determine whether a specific condition is satisfied or fulfilled, an expression of more than or less than may be used, but this is only a description for expressing an example, and does not exclude description of more than or equal to or less than or equal to. A condition described as ‘more than or equal to’ may be replaced with ‘more than’, a condition described as ‘less than or equal to’ may be replaced with ‘less than’, and a condition described as ‘more than or equal to and less than’ may be replaced with ‘more than and less than or equal to.’

Hereinafter, example embodiments will be described in detail with reference to the accompanying drawings so that those of ordinary skill in the art to which the disclosure belongs to may easily implement the disclosure.

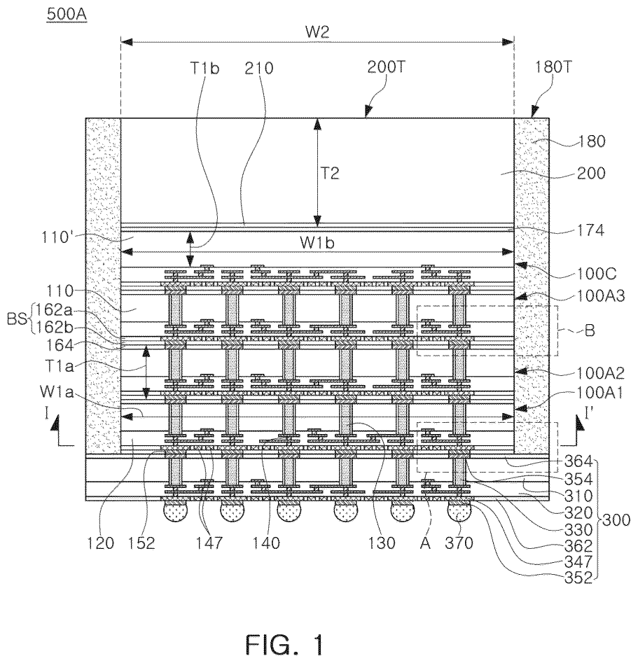

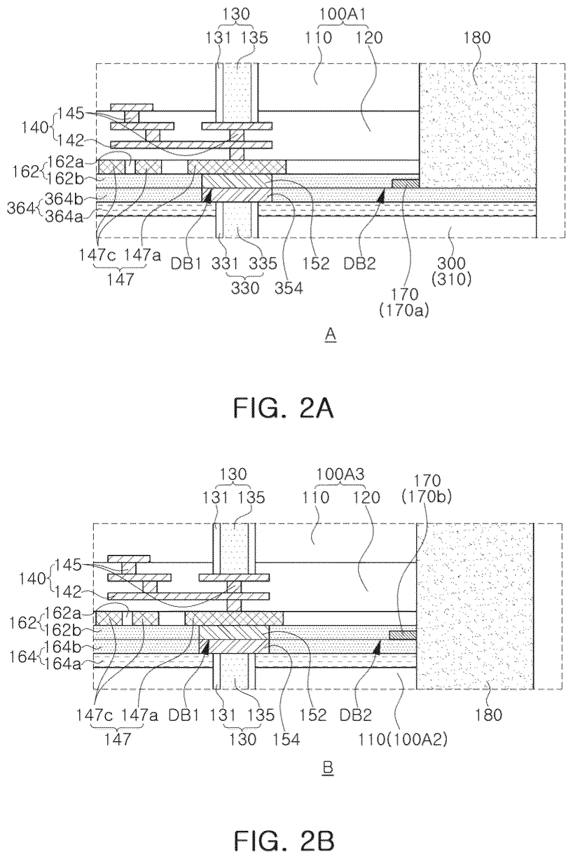

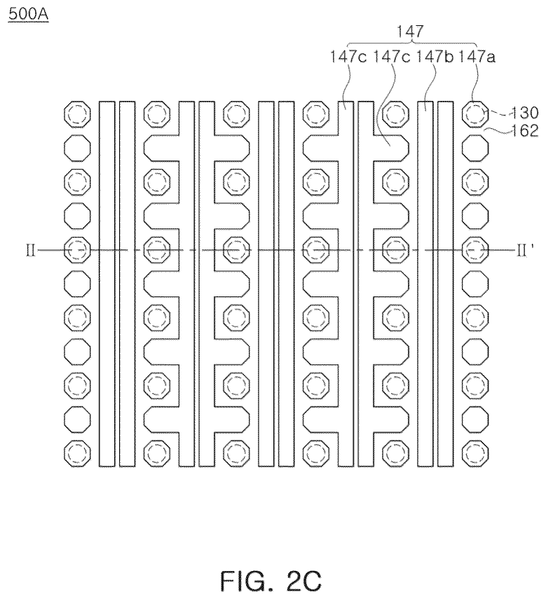

FIG. 1 illustrates an X-Z cross-section taken along lines II to II′ in FIG. 2C, FIG. 2C illustrates an X-Y cross-section taken along lines I to I′ in FIG. 1, FIG. 2A is an enlarged view of a portion A of FIG. 1, and FIG. 2B is an enlarged view of a portion B of FIG. 1.

Referring to FIGS. 1, 2A, 2B and 2C, a semiconductor package 500A according to an example embodiment of the disclosure may include at least one of a plurality of semiconductor chips 100A1, 100A2, 100A3 and 100C, and may further include a base structure 300 disposed below the plurality of semiconductor chips 100A1, 100A2, 100A3 and 100C. Each of the plurality of semiconductor chips 100A1, 100A2, 100A3 and 100C may include a front insulating layer 162b, a plurality of front pads 152, a device layer 120 and semiconductor substrates 110 and 110′. In some embodiments, each of the plurality of semiconductor chips 100A1, 100A2, 100A3 and 100C may further include a conductive pattern 147 and a support insulating layer 162a. Each of the plurality of semiconductor chips 100A1, 100A2 and 100A3 may include a through-via 130, a rear insulating layer 164, and a plurality of rear pads 154. FIG. 1 illustrates a structure in which the number of semiconductor chips 100A1, 100A2, 100A3 and 100C is four. However, the number of semiconductor chips 100A1, 100A2, 100A3 and 100C is not particularly limited.

The plurality of semiconductor chips 100A1, 100A2, 100A3 and 100C may be memory chips. For example, the memory chip may be a volatile memory chip such as a Dynamic Random Access Memory (DRAM) or a Static Random Access Memory (SRAM), or may be a non-volatile memory chip such as a Phase-change Random Access Memory (PRAM), a Magnetoresistive Random Access Memory (MRAM), a Ferroelectric Random Access Memory (FeRAM), or a Resistive Random Access Memory (RRAM). Alternatively, some of the plurality of semiconductor chips 100A1, 100A2, 100A3 and 100C may be memory chips and others thereof may be logic chips. The logic chip may be, for example, a microprocessor, an analog element, or a digital signal processor, and may control an operation of memory chips. For example, a combination of a plurality of semiconductor chips 100A1, 100A2, 100A3 and 100C may be a high bandwidth memory (HBM) DRAM.

The base structure 300 may include lower connection pads 352 disposed on a lower surface thereof and upper connection pads 354 disposed on an upper surface thereof. For example, the base structure 300 may have a width (i.e., area) greater than widths Wla and W1b (i.e., area) of the plurality of semiconductor chips 100A1, 100A2, 100A3 and 100C. The base structure 300 may include a substrate body 310, and a wiring circuit connecting the lower connection pads 352 and the upper connection pads 354 in the substrate body 310. A connection bump 370 may be attached to the lower connection pads 352 of the base structure 300. The connection bump 370 may be, for example, a solder ball or a conductive bump. The connection bump 370 may be electrically connected to the semiconductor package 500A and a printed circuit board, such as a mother board. Alternatively, the connection bump 370 may be electrically connected to an interposer for redistribution on a lower side. The base structure 300 may be implemented as a semiconductor chip, but the disclosure is not limited thereto. For example, in an embodiment, the base structure 300 may be implemented with the interposer.

The semiconductor substrates 110 and 110′ may be disposed above (behind) the device layer 120, and may include semiconductors such as silicon. For example, the semiconductor substrate 110 may include various impurity regions for individual devices, and a device isolation structure such as a ‘shallow trench isolation’ (STI) structure. The semiconductor is not limited to silicon, and may include at least one of germanium, silicon carbide (SiC), gallium arsenide (GaAs), indium arsenide (InAs), and indium phosphide (InP). For example, the device may include a planar MOSFET (Metal Oxide Semiconductor FET), a FinFET whose active region has a fin structure, MBCFET™ (Multi Bridge Channel FET) or Gate-All-Around transistor including a plurality of channels stacked vertically on the active region, or a Vertical FET (VFET), but the disclosure is not limited thereto.

Each of the through-vias 130 may have a pillar structure that penetrates the semiconductor substrate 110. The through-vias 130 may not penetrate through the semiconductor substrate 110′. An upper end of the through-via 130 may be connected to a plurality of rear pads 154, and a lower end thereof may be electrically connected to a plurality of front pads 152 through a wiring structure 140. The through-via 130 may include a via plug 135 and an insulating liner 131 surrounding the via plug 135. As shown in FIG. 2A, the insulating liner 131 may electrically separate the via plug 135 from the semiconductor substrate 110. The through-vias 330, the insulating liner 331, and the via plug 335 of the base structure 300 may be implemented in substantially the same manner as the through-vias 130, the insulating liner 131, and the via plug 135, respectively.

The device layer 120 may include a wiring structure 140 connected to a plurality of individual devices formed on a front surface (lower surface) of the semiconductor substrates 110 and 110′. The wiring structure 140 may include a wiring layer 142 and a wiring via 145. For example, the wiring structure 140 may have a structure in which a plurality of wiring layers 142 are stacked in a Z-direction, and may include a plurality of wiring vias 145 electrically connecting the plurality of wiring layers 142 in the Z-direction. The wiring structure 140 may be electrically connected to a plurality of front pads 152 disposed in front (lower side) of the device layer 120. The wiring layer 142 and the wiring via 145 may include at least one of copper (Cu), a copper alloy, aluminum (Al), and an aluminum alloy. The metallic material is not limited thereto, and may also be implemented as at least of nickel (Ni), gold (Au), cobalt (Co), tantalum (Ta), tellurium (Te), titanium (Ti), tungsten (W) or alloys thereof (e.g. TiN, TaN). A space in the device layer 120 in which the wiring structure 140 is not disposed may be filled with an insulating layer. For example, the insulating layer may include at least one of silicon oxide (SiO), silicon nitride (SiN), silicon oxynitride (SiON), silicon oxycarbide (SiOC), and silicon carbonitride (SiCN). The device layer 320 of the base structure 300 may be implemented in substantially the same manner as the device layer 120.

A plurality of front pads 152 may be disposed on a front surface (bottom surface) of each of the plurality of semiconductor chips 100A1, 100A2, 100A3 and 100C, and may provide electrical paths to the outside of each of the plurality of semiconductor chips 100A1, 100A2, 100A3 and 100C. An exterior of each of the semiconductor chips 100A2, 100A3 and 100C may be or correspond to a plurality of rear pads 154 of the semiconductor chips 100A1, 100A2 and 100A3 immediately below. That is, the plurality of front pads 152 may be connected to the plurality of rear pads 154, and may provide an electrical connection path between the plurality of semiconductor chips 100A1, 100A2, 100A3 and 100C. The plurality of rear pads 154 may be disposed on a rear surface (upper surface) of each of the plurality of semiconductor chips 100A1, 100A2 and 100A3, and may be connected between the plurality of front pads 152 and the through-vias 130.

A front surface (lower surface) and a rear surface (upper surface) of each of the plurality of front pads 152 and the plurality of rear pads 154 may be polygonal or circular, and may have a wider width than a line width of the wiring of the wiring layer 142. Each of the plurality of front pads 152 and the plurality of rear pads 154 may include a metallic material that has high conductivity and can be bonded to each other, such as copper (Cu) or a copper alloy. The metallic material is not limited to copper, and may be implemented with at least one of aluminum (Al), nickel (Ni), gold (Au), cobalt (Co), tantalum (Ta), tellurium (Te), titanium (Ti), tungsten (W), or an alloy thereof. For example, the plurality of front pads 152 and the plurality of rear pads 154 are pre-bonded to make direct contact, and may be then firmly bonded by mutual diffusion of copper through a high temperature annealing process.

The front insulating layer 162b may surround the plurality of front pads 152 in front (lower side) of the device layer 120, and the rear insulating layer 164 may surround the plurality of rear pads 154. The front surfaces (lower surfaces) and rear surfaces (upper surfaces) of the front insulating layer 162b and the plurality of front pads 152 may be coplanar, respectively. The front surfaces (lower surfaces) and rear surfaces (upper surfaces) of the rear insulating layer 164 and the plurality of rear pads 154 may be coplanar, respectively.

Each of the front insulating layer 162b and the rear insulating layer 164 may include at least one of SiN, SiCN, SiO₂, and tetraethyloxysilane (TEOS). When the front insulating layer 162b and the rear insulating layer 164 are bonded to each other, N, C and O of SiN, SiCN, and SiO₂ may be covalently bonded to silicon. Accordingly, the front insulating layer 162b and the rear insulating layer 164 may have strong bonding strength to each other. In an embodiment, each of the front insulating layer 162b and the rear insulating layer 164 may include a plurality of insulating layers. In an embodiment, the plurality of insulating layers may include different insulating materials, among SiN, SiCN, SiO₂, and TEOS.

For example, the rear insulating layer 164 may include a first insulating layer 164a and a second insulating layer 164b. The first insulating layer 164a may prevent undesired electrical connection between the plurality of rear pads 154 and the semiconductor substrate 110. Additionally, the plurality of rear pads 154 may be buried in a second insulating layer (film) 164b so that a rear surface thereof (upper surface) is exposed. An exposed rear surface (upper surface) of the plurality of rear pads 154 may have a rear surface (upper surface) that is substantially flat with the rear surface (upper surface) of the second insulating layer (film) 164b. In some example embodiments, the first and second insulating layers (films) 164a and 164b may be formed of the same material, but the disclosure is not limited thereto, and the first and second insulating layers (films) 164a and 164b may be formed of different materials. For example, the first insulating layer 164a may include silicon nitride or silicon oxynitride, and the second insulating layer 164b may include silicon oxide.

As shown in FIGS. 2A and 2B, the plurality of semiconductor chips 100A1, 100A2, 100A3 and 100C may be bonded to each other through direct bonding DB2 between the front insulating layer 162b and the rear insulating layer 164. Additionally, the plurality of semiconductor chips 100A1, 100A2, 100A3 and 100C may be electrically connected to each other through direct bonding DB1 between the plurality of front pads 152 and the plurality of rear pads 154. The direct bonding DB1 may be intermetallic bonding, and the direct bonding DB2 may be inter-dielectric bonding. A combination of direct bonding DB1 and DB2 may be hybrid bonding.

A lowermost semiconductor chip 100A1, among the plurality of semiconductor chips 100A1, 100A2 and 100A3, may be directly bonded to the aforementioned direct bonding DB1 and DB2 on the base structure 300. Specifically, the plurality of front pads 152 of the semiconductor chip 100A1 adjacent to the base structure 300 may be directly bonded to the upper connection pads 354 to form direct bonding DB1. This direct bonding DB1 may bond the base structure 300 and the semiconductor chip 100A1 to each other and simultaneously ensure electrical connection. An upper bonding insulating layer 364 may be formed on an upper surface of the base structure 300 adopted in this example embodiment, and the upper bonding insulating layer 364 may have an upper surface that is substantially flat with the upper connection pads 354. The upper bonding insulating layer 364 of the base structure 300 and the front insulating layer 162b of the lowermost semiconductor chip 100A1 may be directly bonded to each other, thus forming direct bonding DB2. In this manner, the base structure 300 and the lowermost semiconductor chip 100A1 may be hybrid bonded. For example, the upper bonding insulating layer 364 may include a first insulating layer (film) 364a and a second insulating layer (film) 364b, and may be implemented in substantially the same manner as the first insulating layer (film) 164a and the second insulating layer (film) 164b.

Due to at least one of the direct bonding DB1 and DB2, conductive structures having a relatively low melting point, such as a bump or a solder, may not be disposed between the plurality of semiconductor chips 100A1, 100A2, 100A3 and 100C. Generally, the conductive structures (e.g., a bump and a solder) may be formed through a reflow process or a thermal compression bonding (TCB) process, and may require a minimum width or pitch to ensure reliability.

Due to at least one of the direct bonding DB1 and DB2, the plurality of semiconductor chips 100A1, 100A2, 100A3 and 100C may be bonded to each other without using the conductive structure (e.g., a bump and a solder), and may be advantageous to reduce a width or a pitch of each of the plurality of front pads 152 and the plurality of rear pads 154. Accordingly, the plurality of semiconductor chips 100A1, 100A2, 100A3 and 100C may efficiently increase the integration of the plurality of front pads 152 and the plurality of rear pads 154. As the integration of the plurality of front pads 152 and the plurality of rear pads 154 increases, the integration of electrical paths (e.g., paths through which at least one of a data signal, a control signal, a power signal, and a ground signal passes) of the plurality of semiconductor chips 100A1, 100A2, 100A3 and 100C may also be increased. Accordingly, the semiconductor package 500A may be more advantageous for miniaturization and high performance. Alternatively, due to at least one of the direct bonding DB1 and DB2, electrical reliability (e.g., impedance stability, reduced equivalent series resistance, signal integrity, power integrity, etc.) between the plurality of front pads 152 and the plurality of rear pads 154 may be further improved.

Due to at least one of the direct bonding DB1 and DB2, since the front surface and the rear surface of the plurality of semiconductor chips 100A1, 100A2, 100A3 and 100C may be in direct contact with each other, flatness of the front surface and the rear surface may become more decisive. As the flatness of the front surface and the rear surface increases, the reliability of the plurality of front pads 152 and the plurality of rear pads 154 (e.g., poor contact or electrical short prevention performance) and the reliability of the front insulating layer 162b and the rear insulating layer 164 (e.g., a pore or crack prevention performance) may be improved.

As shown in FIGS. 2A and 2B, the front insulating layer 162b may include a burr 170 disposed in an edge of a front surface (lower surface) of the front insulating layer 162b to surround the plurality of front pads 152. The burr 170 may be formed in the process of dividing a semiconductor wafer into a plurality of semiconductor chips 100A1, 100A2 and 100A3 by dicing. A level of the burr 170 may be dependent on a level of an edge of the front surface of the front insulating layer 162b when the burr 170 is formed. When the burr 170 protrudes further forward than a central region of the front surface (lower surface) of the front insulating layer 162b, the overall flatness of the front surface of the front insulating layer 162b may be deteriorated, and the reliability of the direct bonding DB1 and DB2 may also be deteriorated (e.g., micro-void formation).

The front insulating layer 162b may include the burr 170 buried in an edge of a front surface (lower surface) of the front insulating layer 162b to surround the plurality of front pads 152. The burr 170 may be disposed to step rear from the edge of the front (lower surface) of the front insulating layer 162b to surround the plurality of front pads 152. For example, the edge of the front (lower surface) of the front insulating layer 162b may have a step portion, the front surface (lower surface) of the front insulating layer 162b may be disposed further rearward (upwards) compared to a central region of the front insulating layer 162b. Accordingly, since the burr 170 may not protrude further than the central region of the front surface (lower surface) of the front insulating layer 162b, and the overall flatness of the front surface of the front insulating layer 162b may be improved, and the reliability of the direct bonds DB1 and DB2 may also be improved, and electrical reliability (e.g., impedance stability, reduced equivalent series resistance, signal integrity, power integrity, etc.) between the plurality of front pads 152 and the plurality of rear pads 154 may also be improved.

Referring to FIGS. 2A and 2B, a cross-sectional shape of the burr 170 may be square, and an edge of the front surface (lower surface) of the front insulating layer 162b may be substantially the same as a shape of the step portion. When the burr 170 is formed, the burr 170 may have a shape that protrudes convexly forward (downwardly) within the step portion, but in a process of direct bonding DB1 and DB2, the burr 170 may be transformed to become closer to a square according to the tendency to fill the empty space within the step portion. Since a difference between a volume of the step portion and a volume of the burr 170 may affect a specific shape of the burr 170, the specific shape of the burr 170 is not particularly limited.

In FIGS. 2A and 2B, a burr 170a of the semiconductor chip 100A1 and a burr 170b of a semiconductor chip 100A3 may be substantially identical to each other. Accordingly, a semiconductor package 500A according to an example embodiment of the disclosure may include a plurality of burrs 170a and 170b respectively disposed on at least two of the plurality of semiconductor chips 100A1, 100A2, 100A3 and 100C, and each of the plurality of burrs 170a and 170b may be buried in an edge of the front surface (lower surface) of each of the plurality of front insulating layers 162b or may be disposed to step back.

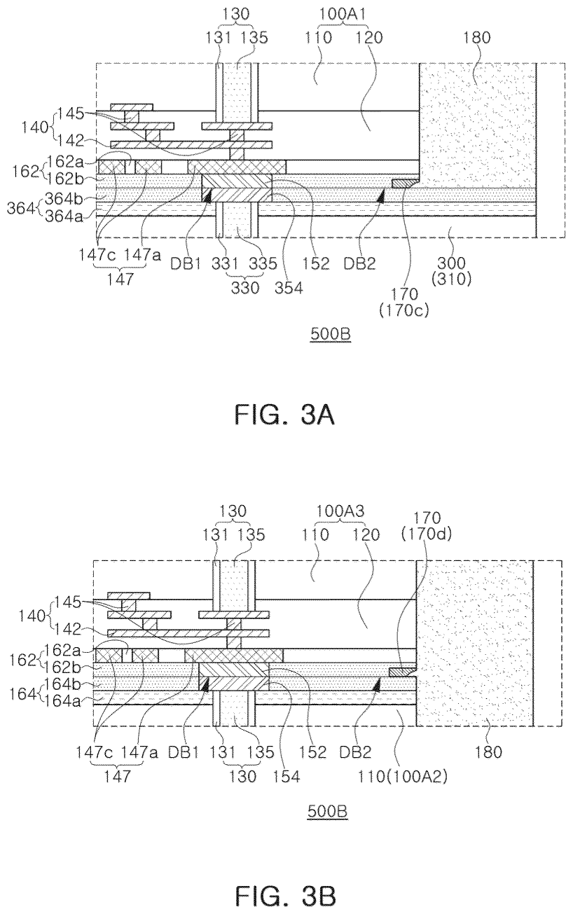

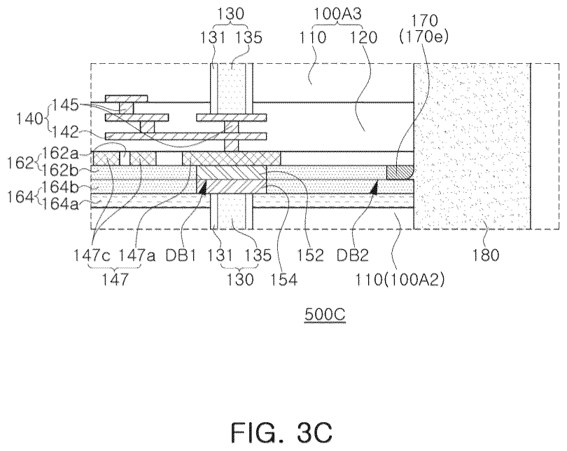

FIGS. 3A to 3C illustrate enlarged portions of semiconductor packages 500B and 500C according to an example embodiment of the disclosure, and the portions may correspond to portions A and B of FIG. 1. Referring to FIGS. 3A to 3C, side surfaces of the burrs 170c, 170d, and 170e may have a recessed shape, and may have a curved shape. Referring to FIGS. 3A and 3B, the side surfaces of the burrs 170c and 170d may be more recessed and more curved than a side surface of a portion of the front insulating layer 162b overlapping the burrs 170c and 170d in a front-rear direction (up and down direction).

For example, a portion of a side surface of the burrs 170c, 170d and 170e facing a center region of the front insulating layer 162b may be modified to be closer to a boundary of the step portion according to the tendency to fill an empty space in the step portion during a process of the direct bonding DB1 and DB2. On the other hand, a shape of a portion of the side surface of the burrs 170c, 170d and 170e facing a molding portion 180 may have a recessed shape because there is no significant deformation during the process of the direct bonding DB1 and DB2. The burrs 170c, 170d and 170e may be asymmetrical on both sides.

Referring to FIGS. 3A and 3B, the burrs 170c and 170d may be disposed to overlap a portion of the front insulating layer 162b in the front-rear direction (up and down direction). That is, a length of the burrs 170c and 170d in the front-rear direction may be shorter than a thickness of the front insulating layer 162b. Referring to FIG. 3C, the burr 170e may not overlap the front insulating layer 162b in the front-rear direction (up and down direction). Whether the burrs 170c, 170d and 170e overlap the front insulating layer 162b in the front-rear direction (up and down direction) may be determined by a thickness of the front insulating layer 162b, a thickness of the device layer 120, or dicing process factors.

FIGS. 3C, FIGS. 4A and 4B, FIGS. 5A to 5G will be described later.

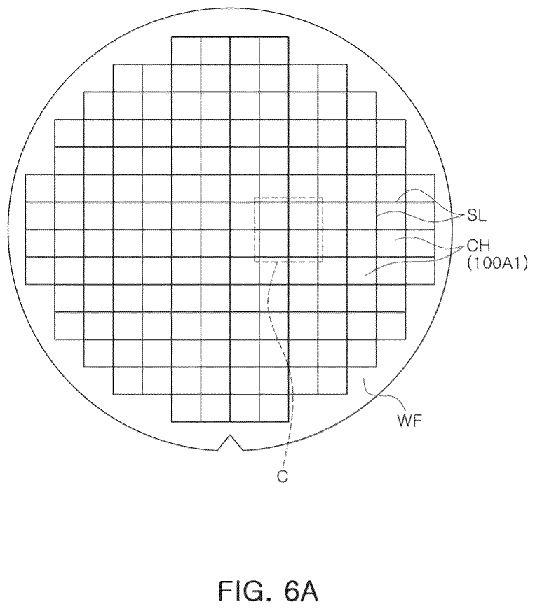

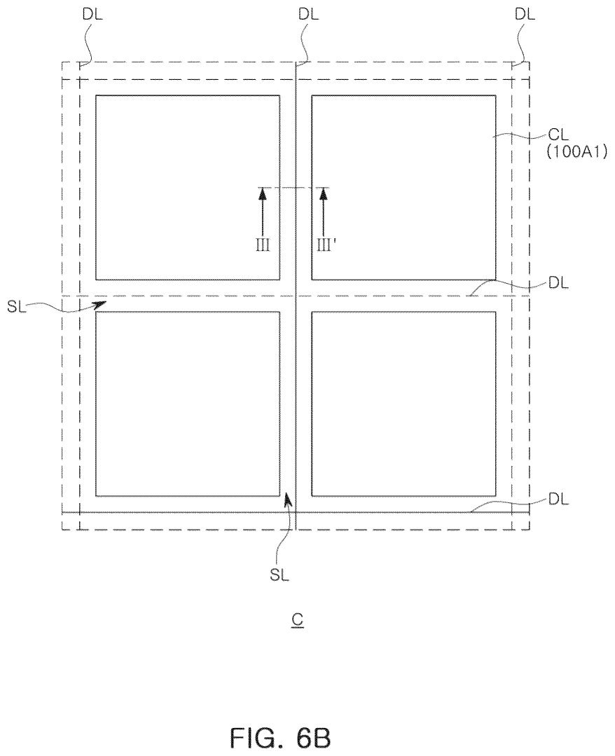

FIGS. 6A and 6B are plan views illustrating a scribe lane region SL in a semiconductor wafer WF, and FIG. 6B is an enlarged view of region ‘C’ of FIG. 6A.

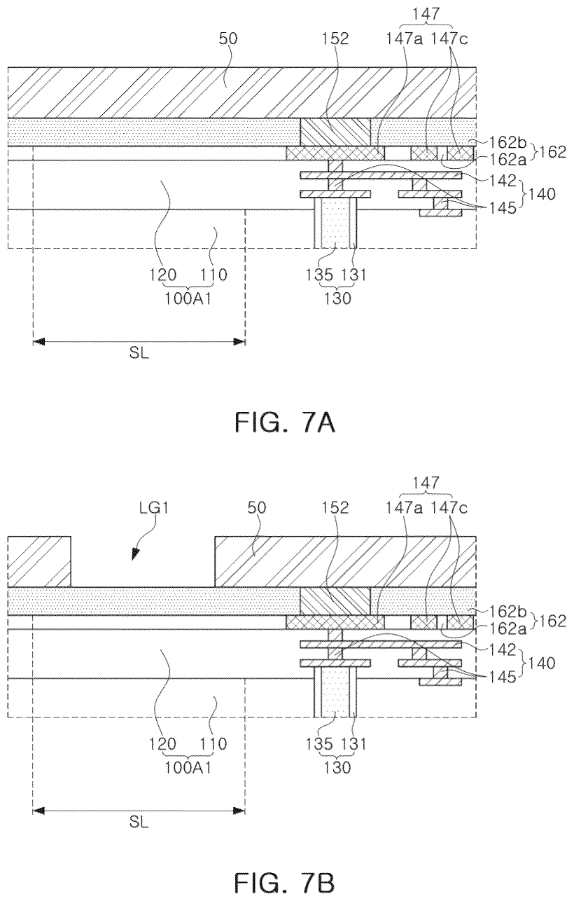

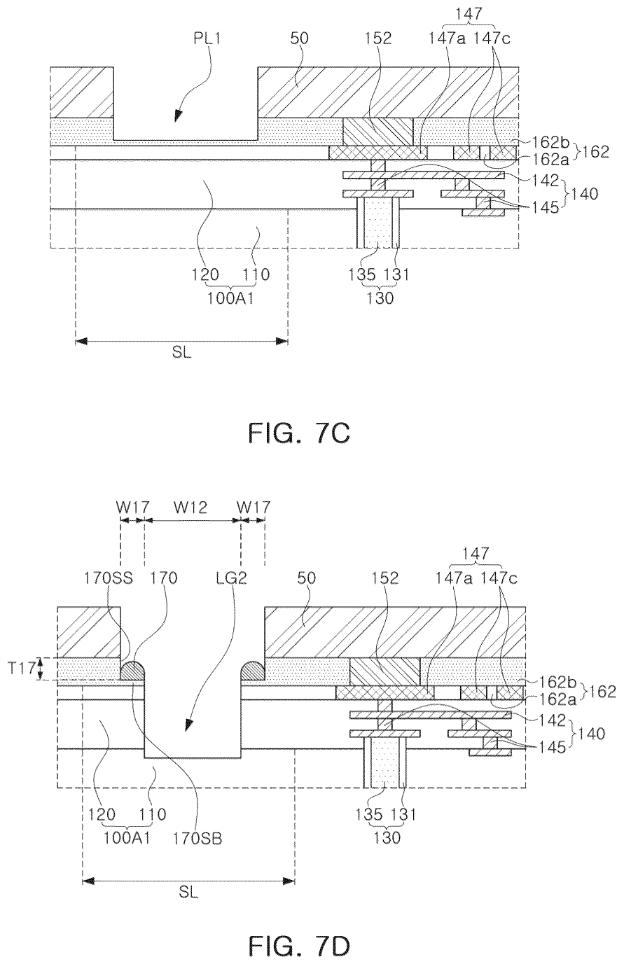

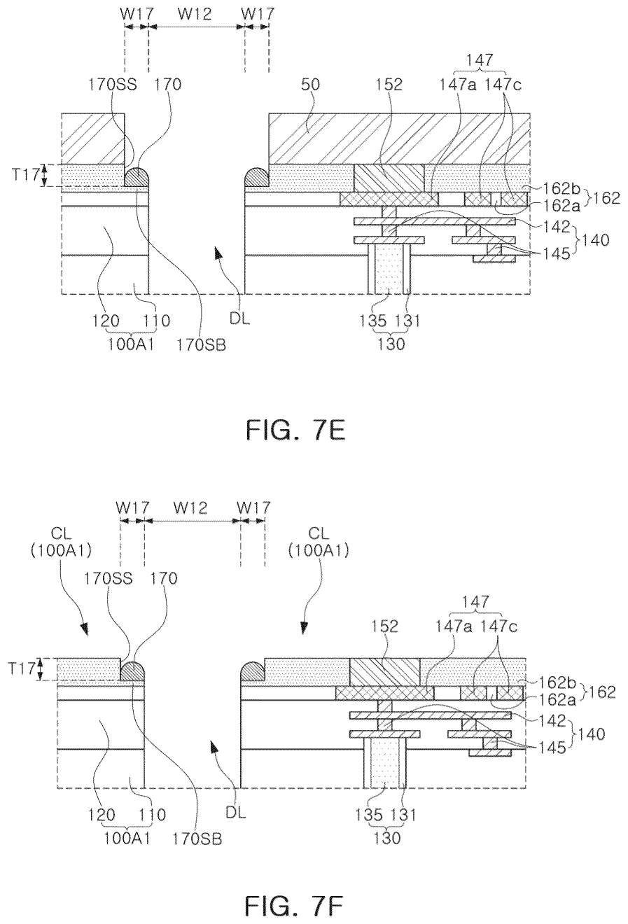

Referring to FIGS. 6A and 6B, a semiconductor wafer WF including a plurality of chip regions CH and a plurality of scribe lane regions SL between the plurality of chip regions CH may be prepared. The semiconductor wafer WF may be a semiconductor wafer before dicing is performed. The plurality of scribe lane regions SL may include a region through which the dicing line DL passes. Here, the dicing line DL may be a virtual line. The dicing process to be described below may cut the semiconductor wafer WF along the dicing line DL. The plurality of chip regions CH may correspond to a semiconductor chip 110A1 of FIGS. 1 to 2C. The semiconductor wafer WF may include a semiconductor substrate 110, a device layer 120, and a front insulating layer 162b of FIGS. 7A to 7F.

FIGS. 7A to 7F illustrate a semiconductor package manufacturing method according to an example embodiment of the disclosure, and illustrate an X-Z cross section taken along lines III to III′ of FIG. 6B.

Referring to FIGS. 7A and 7B, the semiconductor package manufacturing method according to an example embodiment of the disclosure may include forming a mask layer 50 in front (upper side) of a wafer including a semiconductor substrate 110, a device layer 120 disposed in front (upper side) of the semiconductor substrate 110, and a front insulating layer 162b disposed in front (upper side) of the device layer 120.

The operation of forming the mask layer 50 may include adding the mask layer 50 (see FIG. 7A) as well as removing a portion (LG1) of the added mask layer 50 (see FIG. 7B). The mask layer 50 may be formed of a non-photosensitive material such as ‘protection layer coating’ (PLC). In an embodiment, the mask layer 50 may be formed from a photosensitive material such as a photo resist. Removing the portion (LG1) of the added mask layer 50 (see FIG. 7b) may be implemented by locally irradiating laser to an entire portion (LG1) or a boundary using a laser grooving process.

Referring to FIG. 7C, the semiconductor package manufacturing method according to an example embodiment of the disclosure may include forming a step portion in an edge of a front surface (upper surface) of the front insulating layer 162b by removing the portion (PL1) of the front insulating layer 162b that does not overlap the mask layer 50 in the front-rear direction (up and down direction) along the scribe lane region (SL) of the wafer.

The operation of forming the step portion may include using a plasma process. For example, the plasma process may include using at least one gas of O₂, CxFy, and CHxFy. Here, x and y are natural numbers, for example, CxFy may be C4F8 or C4F6, and CHxFy may be CH2F2.

Referring to FIG. 7D, a semiconductor package manufacturing method according to an example embodiment of the disclosure may include removing another portion of the front insulating layer 162b having a width W12 narrower than a width (W17+W12+W17) of a portion of the front insulating layer 162b along the scribe lane region SL, and a portion LG2 of the device layer 120.

For example, the operation of removing the portion LG2 of the device layer 120 may use a laser grooving process, which may melt or vaporize the portion LG2 by absorbing a high level of pulse energy on a surface of the portion LG2 and heating the portion LG2 to several thousand degrees for a short period of time (e.g. a pulse cycle). During the laser grooving process (a melting/vaporization process), since heat energy equal to or less than a processing threshold may be conducted near the portion LG2 (e.g., an edge of the front insulating layer 162b), materials present in the portion LG2 of the device layer 120 may undergo a melting/recrystallization process. Accordingly, some of the materials (insulating materials of the device layer 120 and/or metallic materials of the wiring structure 140) that were present in the portion LG2 of the device layer 120 may be included in the burr 170 formed in step portions 170SB and 170SS of the front insulating layer 162b, as shown in FIG. 7D.

For example, the burr 170 may include an insulating material (e.g., SiO₂) different from the material included in the front insulating layer 162b (e.g., at least one of SiN, SiCN, and tetraethyloxysilane (TEOS)). For example, the burr 170 may include a metallic material (e.g., aluminum or an aluminum alloy) different from the metallic material (e.g., copper or copper alloy) included in the plurality of front pads 152.

A height T17 of the step portions 170SB and 170SS may be greater than or equal to a height of the burr 170, and a product of the height T17 and a width W17 of the step portions 170SB and 170SS may be greater than or equal to a volume of the burr 170 so that the burr 170 does not affect the flatness of the front surface (upper surface) of the front insulating layer 162b.

According to data that can be obtained by repeatedly experimenting the operation of removing the portion LG2 of the device layer 120, an average height and a standard deviation of the burr 170 are 1.04 μm and 0.42 μm, respectively, and an average width and a standard deviation of the burr 170 are 4.00 μm and 0.243 μm, respectively.

The height T17 of the step portions 170SB and 170SS may be 2.5 μm or more, which is slightly larger than a sum (2.3 μm) of the average height (1.04 μm) of the burr 170 and three times a standard deviation thereof (1.26 μm), and the width W17 of the step portions 170SB and 170SS may be 5 μm or more, which is slightly larger than the sum (4.729 μm) of the average width (4.00 μm) of the burr 170 and three times a standard deviation thereof (0.73 μm). Accordingly, the step portions 170SB and 170SS may prevent the burr 170 from protruding further forward (upwardly) than a central region of the front surface (upper surface) of the front insulating layer 162b. The height T17 of the step portions 170SB and 170SS may be longer than the width W17 of the step portions 170SB and 170SS.

For example, each of the widths W17 and W12) and the height T17 may be measured by means of an analysis using at least one of Transmission Electron Microscopy (TEM), Atomic Force Microscope (AFM), Scanning Electron Microscope (SEM), optical microscope, and surface profiler, and may be calculated as an average value in the corresponding pixels.

The operation of removing another portion of the front insulating layer 162b and the portion LG2 of the device layer 120 may include using a femtosecond laser grooving process. Compared to a nanosecond laser grooving process, the femtosecond laser grooving process may be advantageous in reducing the volume of the burr 170. Therefore, the femtosecond laser grooving process may be advantageous in reducing the height T17 and the width W17 of the step portions 170SB and 170SS of the front insulating layer 162b, and may be advantageous in ensuring the flatness of the front surface (upper surface) of the front insulating layer 162b.

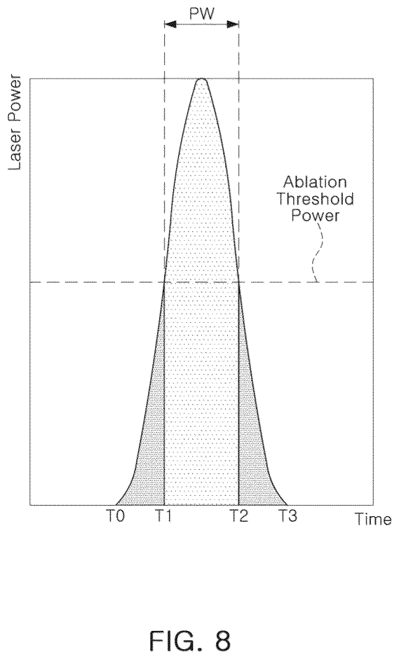

Referring to FIG. 8, the laser power of the femtosecond laser may be output from time T0 to time T3, and a period PW from T1 time to T2 time may be a femtosecond (1 fs or more and 999 fs or less). T1 time and T2 time may be a time when the laser power is half the peak value (Ablation Threshold Power), and may be a time when a target (e.g., LG2 of FIG. 7D) from which the femtosecond laser is output starts or ends to be effectively melted/vaporized. As the cycle PW is reduced, a boundary between a region melted/vaporized by the femtosecond laser (e.g., LG2 in FIG. 7D) and a region that is not melted/vaporized may be more distinct, and thus, a phenomenon of forming the burr 170 by melting/recrystallization on the boundary may be reduced.

Referring to FIG. 7E, a semiconductor package manufacturing method according to an example embodiment of the disclosure may include removing a portion of the semiconductor substrate 110 along the scribe lane region SL. A portion of the semiconductor substrate 110 may correspond to a dicing line DL. For example, the operation of removing a portion of the semiconductor substrate 110 may include alternating and repeated use of SF6 plasma gas and C4F8 plasma gas. Accordingly, a side surface of the semiconductor substrate 110 may be uneven, but since the operation of removing a portion of the semiconductor substrate 110 may further include using NF3 plasma gas, the unevenness of the side surface can be alleviated. Then, a portion of a rear insulating layer disposed on the rear (lower side) of the semiconductor substrate 110 (a portion overlapping the scribe lane region SL) may be removed.

Referring to FIG. 7F, a semiconductor package manufacturing method according to an example embodiment of the disclosure may include removing the mask layer 50. Accordingly, the semiconductor package 500A illustrated in FIGS. 1 to 2C may not include the mask layer.

Meanwhile, referring again to FIGS. 1 to 2B, the conductive pattern 147 may be disposed between the wiring structure 140 and the plurality of front pads 152. The support insulating layer 162a may be disposed between the device layer 120 and the front insulating layer 162b to surround the conductive pattern 147. Front surfaces (lower surfaces) and rear surfaces (upper surfaces) of the conductive pattern 147 and the support insulating layer 162a may each be coplanar. A conductive pattern 347 and a support insulating layer 362 of the base structure 300 may be implemented in substantially the same manner as the conductive pattern 147 and the support insulating layer 162a.

When the plurality of front pads 152 are coupled to the plurality of rear pads 154 in an annealing process, the conductive pattern 147 as well as the plurality of front pads 152 may be thermally expanded. Thermal expansion of the conductive pattern 147 may support thermal expansion of the plurality of rear pads 154 of the plurality of front pads 152. Accordingly, the plurality of front pads 152 and the plurality of rear pads 154 may be more efficiently coupled to each other. As a coupling efficiency between the plurality of front pads 152 and the plurality of rear pads 154 increases, a minimum volume required for the plurality of front pads 152 and the plurality of rear pads 154 may be reduced. Accordingly, a width or a pitch of the plurality of front pads 152 and the plurality of rear pads 154 may be further refined, and the integration of electrical paths of the plurality of semiconductor chips 100A1, 100A2, 100A3 and 100C may also be further increased.

The support insulating layer 162a may be implemented in the same manner as the front insulating layer 162b. For example, the support insulating layer 162a may include at least one of SiO₂, SiN, SiCN, and tetraethyloxysilane (TEOS). The conductive pattern 147 may be implemented in the same manner (e.g., the same material and/or the same process) as the wiring layer 142 of the wiring structure 140. Accordingly, the conductive pattern 147 may be a lowermost wiring layer of the wiring structure 140. For example, the conductive pattern 147 may include at least one of copper, a copper alloy, aluminum, and an aluminum alloy.

The conductive pattern 147 may have a thickness greater than a thickness of each of the plurality of wiring layers 142. Since the conductive pattern 147 may have a thickness greater than the thickness of each of the plurality of wiring layers 142, the conductive pattern 147 may have a relatively large volume. As the volume of the conductive pattern 147 increases, the thermal expansion of the plurality of front pads 152 to the plurality of rear pads 154 may be better supported.

In an embodiment, the conductive pattern 147 may include a conductive material (e.g., aluminum) having a higher thermal expansion coefficient than a thermal expansion coefficient of the conductive material (e.g., copper) of the plurality of front pads 152. Since a coefficient of thermal expansion of aluminum is higher than coefficient of thermal expansion of copper, the conductive pattern 147 including aluminum may more efficiently support thermal expansion of the plurality of front pads 152 including copper.

The efficiency in which the conductive pattern 147 supports the thermal expansion bond between the plurality of front pads 152 and the plurality of rear pads 154 may be a trade-off with the flatness (or importance of flatness) of a front surface of the plurality of semiconductor chips 100A1, 100A2, 100A3 and 100C. The semiconductor package 500A according to an example embodiment of the disclosure may ensure one of the thermal expansion bond support efficiency and the flatness (or importance of flatness) while improving the other thereof.

The conductive pattern 147 may include a plurality of pad patterns 147a electrically connected between the wiring structure 140 and the plurality of front pads 152, and dummy patterns 147b and 147c spaced apart from the plurality of front pads 152 and the plurality of pad patterns 147a.

For example, a front surface (lower surface) and a rear surface (upper surface) of the plurality of pad patterns 147a may be polygonal or circular. A width of the plurality of pad patterns 147a may be wider than a width of the plurality of front pads 152. Accordingly, the plurality of pad patterns 147a may support the plurality of front pads 152 more stably.

For example, a portion (e.g., a center portion) of the front surface (lower surface) of the plurality of pad patterns 147a may be in direct contact with the plurality of front pads 152, and another portion (e.g., an edge portion) of the front surface (lower surface) of the plurality of pad patterns 147a may be in direct contact with the front insulating layer 162b. Accordingly, the overall stacking stability of a combination 162 of the support insulating layer 162a and the front insulating layer 162b may be improved, an occurrence of delamination of the combination 162 may be reliably prevented.

The dummy patterns 147b and 147c may fill a portion of peripheral spaces of the plurality of pad patterns 147a so as to prevent the metallic material from concentrating at specific points (e.g., a plurality of pad patterns 147a) in the combination of the conductive pattern 147 and the support insulating layer 162a. Accordingly, even if the conductive pattern 147 is thicker than the wiring layer 142, the combination of the conductive pattern 147 and the support insulating layer 162a may be stably stacked on the front surface (lower surface) of the device layer 120, and the occurrence of delamination of the combination may be reliably prevented. That is, the dummy patterns 147b and 147c may improve the structural stability of the conductive pattern 147 and the surroundings thereof.

The dummy patterns 147b and 147c may be spaced apart from the plurality of pad patterns 147a, and may not be connected to the plurality of front pads 152 and/or wiring structure 140. For example, the plurality of pad patterns 147a may be configured to transmit a signal to the wiring structure 140 to or receive a signal from the wiring structure 140, and the dummy patterns 147b and 147c may have ground or DC voltage. The dummy patterns 147b and 147c may surround the plurality of pad patterns 147a, thus electromagnetically shielding the plurality of pad patterns 147a. Additionally, a relatively large volume of the dummy patterns 147b and 147c may improve the electrical stability of DC voltage or ground.

A total area of the dummy patterns 147b and 147c may be larger than a total area of the plurality of pad patterns 147a. As the total area of the dummy patterns 147b and 147c increases, the dummy patterns 147b and 147c may further improve the structural stability (e.g., prevention of delamination) of the conductive pattern 147 and the surroundings thereof.

Generally, a total area of the dummy patterns 147b and 147c may be increased more efficiently as the connectivity between each portion of the dummy patterns 147b and 147c (or the total number of dummy patterns relative to unit area) increases. However, as the connectivity between each portion of the dummy patterns 147b and 147c (or the total number of dummy patterns relative to unit area) increases, the influence of thermal expansion of the dummy patterns 147b and 147c on the flatness (or importance of flatness) of the front surface of the plurality of semiconductor chips 100A1, 100A2, 100A3 and 100C may increase. Accordingly, the structural stability (e.g., prevention of delamination) of the conductive pattern 147 and the surroundings thereof may be a trade-off with the flatness (or importance of flatness). The semiconductor package 500A according to an example embodiment of the disclosure may secure one of the structural stability and flatness while improving the other thereof.

Referring to FIG. 1, a semiconductor package 500A according to an embodiment of the disclosure may include an upper dummy chip 200 disposed on a rear surface (upper surface) of a semiconductor chip 100C. For example, the upper dummy chip 200 may include a semiconductor such as silicon or a substrate such as metal. In some example embodiments, the upper dummy chip 200 may provide a heat dissipation function and/or an identification mark display region.

The upper dummy chip 200 may have a thickness T2 greater than a thickness T1a of a plurality of semiconductor chips 100A1, 100A2 and 100A3 and a thickness T1b of the semiconductor chip 100C. For example, the thickness T2 of the upper dummy chip 200 may be 200 μm or more, and the thicknesses T1a and T1b may be 100 μm or less.

The upper dummy chip 200 includes a lower bonding insulating layer 210 disposed on a lower surface thereof, and the semiconductor chip 100C includes a rear insulating layer 174 disposed on an upper surface thereof. The lower bonding insulating layer 210 and the rear insulating layer 174 may be directly bonded to each other, and thus, the upper dummy chip 200 may be bonded to the rear surface (upper surface) of the semiconductor chip 100C. As described above, the upper dummy chip 200 and the semiconductor chip 100C may be bonded by dielectric-to-dielectric bonding between the lower bonding insulating layer 210 and the rear insulating layer 174. At least one of the lower bonding insulating layer 210 and the rear insulating layer 174 may include a dielectric layer formed by a deposition process, but may include a natural oxide film formed in a high-temperature annealing process unlike this.

A width W2 (i.e., area) of the upper dummy chip 200 may be identical to a width W1a (i.e., area) of the plurality of semiconductor chips 100A1, 100A2 and 100A3, and may be identical to a width W1b (i.e., area) of the semiconductor chip 100C, but the disclosure is not limited thereto.

Referring to FIG. 1, a semiconductor package 500A according to an example embodiment of the disclosure may include a molding portion 180 that seals the plurality of semiconductor chips 100A1, 100A2, 100A3 and 100C and the upper dummy chip 200. For example, the molding portion 180 may include an epoxy mold compound (EMC).

An upper surface 200T of the upper dummy chip 200 is exposed on an upper surface 180T of the molding portion 180. The exposed upper surface 200T of the upper dummy chip 200 may have a substantially flat coplanar surface with the upper surface 180T of the molding portion 180. The coplanar upper surfaces may be understood as upper surfaces obtained by a polishing process. Furthermore, a side surface of the molding portion 180 may have a substantially flat coplanar surface with a side surface of the base structure 300. The coplanar side surfaces may be understood as side surfaces obtained in the same cutting process.

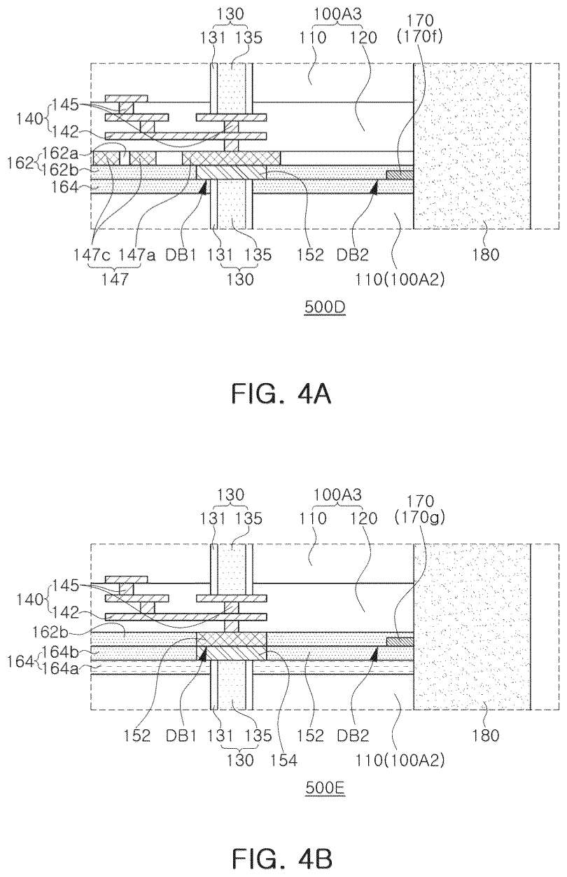

FIGS. 4A and 4B are enlarged views of a portion of semiconductor packages 500D and 500E according to an example embodiment of the disclosure, and the portion may correspond to a portion B of FIG. 1, but may also be implemented in a portion A of FIG. 1.

Referring to FIG. 4A, a semiconductor package 500D according to an example embodiment of the disclosure may have a structure from which the rear pad 154 of FIG. 2B is omitted, and may have a structure in which a front pad 152 and a through-via 130 are in direct contact with each other. A front insulating layer 162b may include a burr 170f buried in an edge of a front surface (lower surface) of the front insulating layer 162b to surround a plurality of front pads 152.

Referring to FIG. 4B, a semiconductor package 500E according to an example embodiment of the disclosure may have a structure from which the conductive pattern 147 and the support insulating layer 162a of FIG. 2B are omitted, and may have a structure in which a front pad 152 and a wiring structure 140 are directly connected to each other. The front insulating layer 162b may include a burr 170g buried in an edge of a front surface (lower surface) of the front insulating layer 162b to surround a plurality of front pads 152.

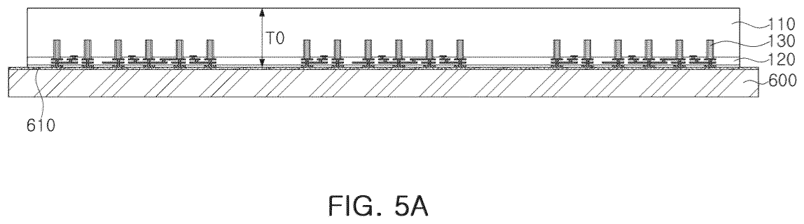

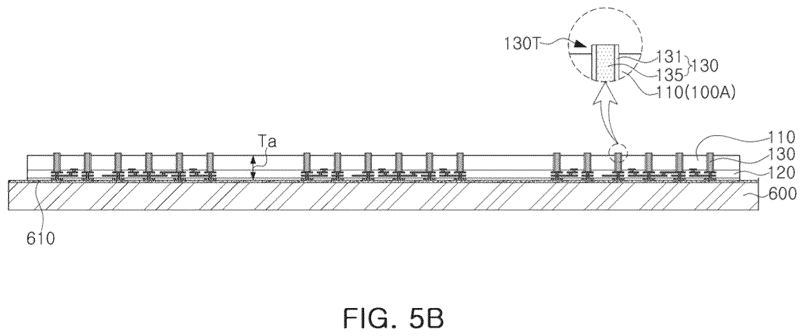

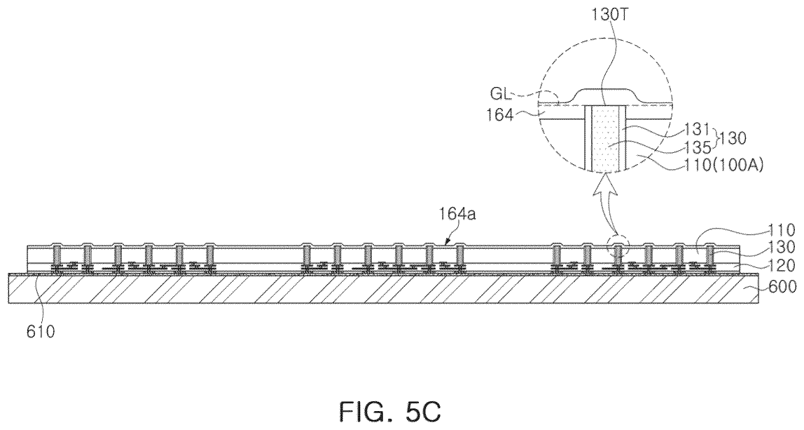

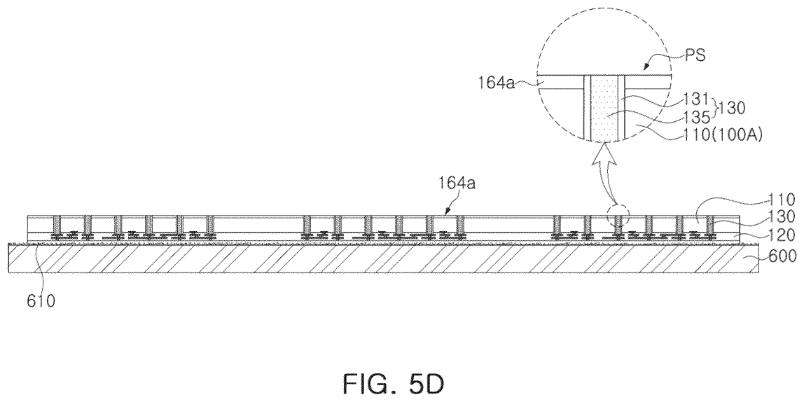

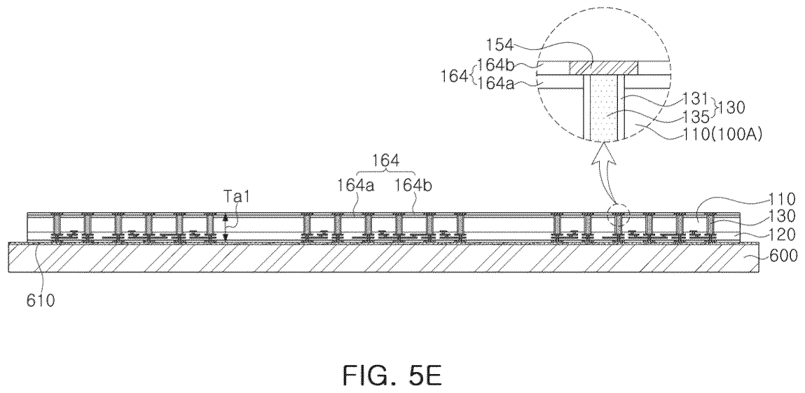

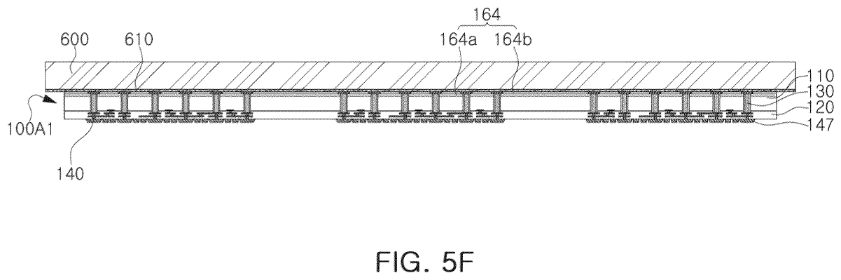

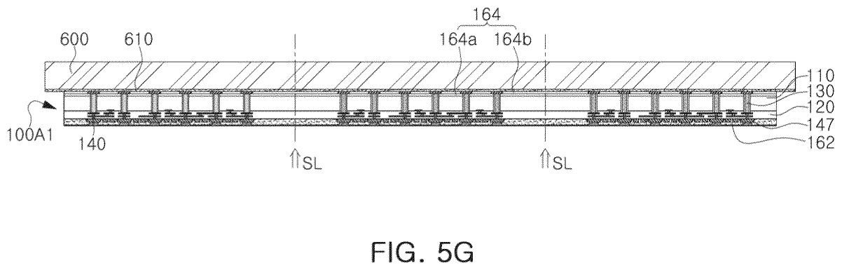

Referring to FIGS. 5A to 5G, a semiconductor package manufacturing method according to an example embodiment of the disclosure may include forming a wafer including a device layer 120, a semiconductor substrate 110, a rear insulating layer 164, a plurality of rear pads 154, and a plurality of front pads 152. The wafer may correspond to a wafer WF of FIGS. 6A and 6B.

Referring to FIG. 5A, a semiconductor substrate 110 for a plurality of semiconductor chips 100A may be bonded onto a carrier substrate 600. In FIG. 5A, the semiconductor substrate 110 is illustrated as a wafer including three semiconductor chips 100A. Individual devices may form a plurality of semiconductor chips on an active surface of the semiconductor substrate 110. Furthermore, on an active surface of the semiconductor substrate 110, through-vias 130 extending into the semiconductor substrate 110, and a device layer 120 connected to the through-vias 130 may be formed. As described above, the semiconductor substrate 110 may be in a state in which a rear surface process is not performed after completing a front process of the semiconductor chip. That is, since the semiconductor substrate 110 is not in a state to which a grinding process is not applied, the semiconductor substrate 110 may have a relatively large first thickness TO. A front surface (lower surface) of the semiconductor substrate 110, i.e., the surface on which the device layer is formed, is bonded to face the carrier substrate 600. Such bonding may be implemented by an adhesive layer 610 such as a UV curable film.

Referring to FIG. 5B, a grinding process is applied to an inactive surface of a semiconductor substrate 110 so that a thickness (T0→Ta) of the semiconductor substrate 110 is reduced. In the present grinding, an upper end 130T of a through-via 130 may be exposed from a ground surface of a semiconductor wafer. Due to a difference in an etching rate, the upper end 130T may protrude from a surface of the semiconductor wafer 100. Through the present process, a thickness of the semiconductor chip 100A may be reduced to a desired thickness Ta. The thickness reduction process may also be performed in an etch-back process or a combination thereof in addition to grinding processes such as chemical mechanical polishing (CMP) processes. In some embodiments, a grinding process may be performed to reduce the thickness of the semiconductor substrate 110, and may sufficiently expose the through-via 130 by applying an etch-back under suitable conditions.

Referring to FIG. 5C, a first insulating layer 164a may be formed on a semiconductor substrate 110 to cover an exposed upper end 130T of a through-via 130. The first insulating layer 164a may be used as a passivation layer. For example, the first insulating layer 164a may include silicon nitride or silicon oxynitride.

Referring to FIG. 5D, a first insulating layer 164a may be ground to expose a through-via 130. A grinding process may be performed up to a predetermined line GL such that the first insulating layer 164a is partially removed so that the through-via 130 is sufficiently exposed. Through the present grinding process, the first insulating layer 164a may have a substantially flat upper surface with respect to an upper surface of the through-via 130. Furthermore, a damaged portion of an upper end 130T of the through-via 130 may be removed.

Referring to FIG. 5E, a plurality of rear pads 154 and a second insulating layer 164b surrounding the plurality of rear pads 154 may be formed on a first insulating layer 164a. Similarly to the previous processes, a plurality of rear pads 154 are formed on the first insulating layer 164a, and a second insulating layer 164b is formed to cover the plurality of rear pads 154. Then, the second insulating layer 164b may be partially removed to perform a grinding process such that rear surfaces (upper surfaces) of the plurality of rear pads 154 are exposed. Through the present grinding process, the second insulating layer 164b may have a rear surface (upper surface) that is substantially flat with rear surfaces (upper surfaces) of the plurality of rear pads 154. For example, the second insulating layer 164b may include silicon oxide. In the present specification, first and second insulating layers 164a and 164b are commonly referred to as a rear insulating layer 164.

Referring to FIG. 5F, a semiconductor package manufacturing method according to an example embodiment of the disclosure may include forming a conductive pattern 147 on a front surface (lower surface) of a device layer 120 of at least one 100A1 of a plurality of semiconductor chips. For example, a conductive pattern 147 may be formed according to a photolithography manner. FIG. 5F illustrates that the conductive pattern 147 is formed after a semiconductor substrate 110, a rear surface insulating layer 164, and a plurality of rear pads 154 are formed. In an embodiment, the conductive pattern 147 may also be formed together with a device layer 120. This is because the conductive pattern 147 may be a portion of a wiring structure 140 of the device layer 120. That is, the step of forming the conductive pattern 147 on a front surface (lower surface) of the device layer 120 of at least one 100A1 of the plurality of semiconductor chips may be a portion of an operation of forming the device layer 120.

Referring to FIG. 5G, a semiconductor package manufacturing method according to an example embodiment of the disclosure may include forming a combination 162 of a support insulating layer 162a and a front insulating layer 162b to form a plurality of front pads 152. For example, the aforementioned operation may further include forming the support insulating layer 162a and then flattening a front surface (lower surface) of the support insulating layer 162a, and the front insulating layer 162b may be formed after planarization of the support insulating layer 162a. For example, the operation may further include forming holes in the front insulating layer 162b, and a plurality of front pads 152 may be formed to fill the holes. The operation may also be performed before a semiconductor substrate 110, a rear insulating layer 164, and a plurality of rear pads 154 are formed, according to the design.

A process illustrated in FIGS. 5F and 5G may include arranging a carrier substrate 600 on a rear surface of the rear insulating layer 164, and the carrier substrate 600 may be separated from the rear insulating layer 164 after forming a plurality of front pads 152, and a completed wafer may be diced along the scribe lane region SL.

Descriptions about FIGS. 6A and 6B, FIGS. 7A to 7F, and FIG. 8 are provided earlier.

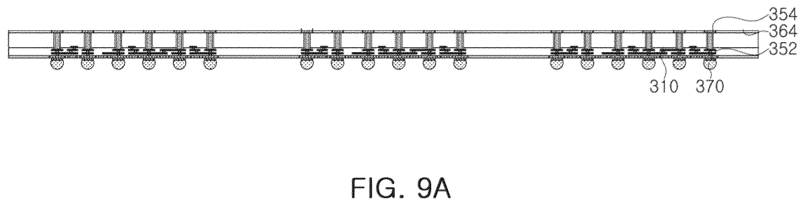

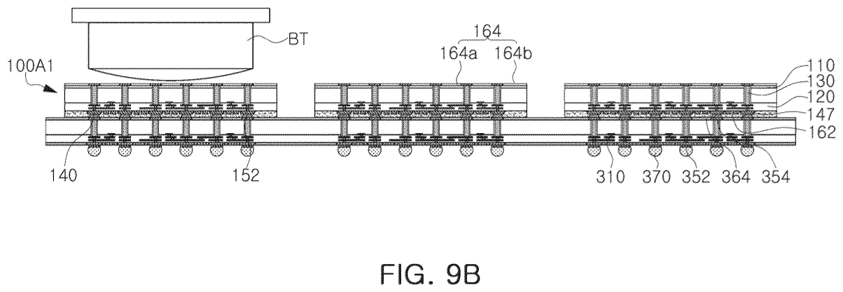

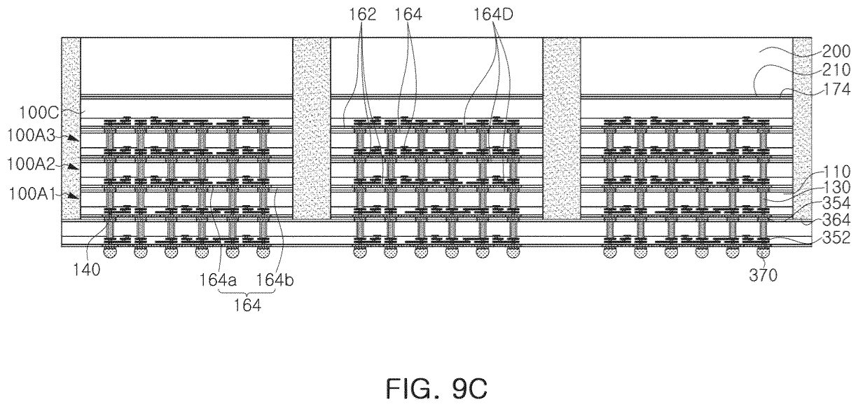

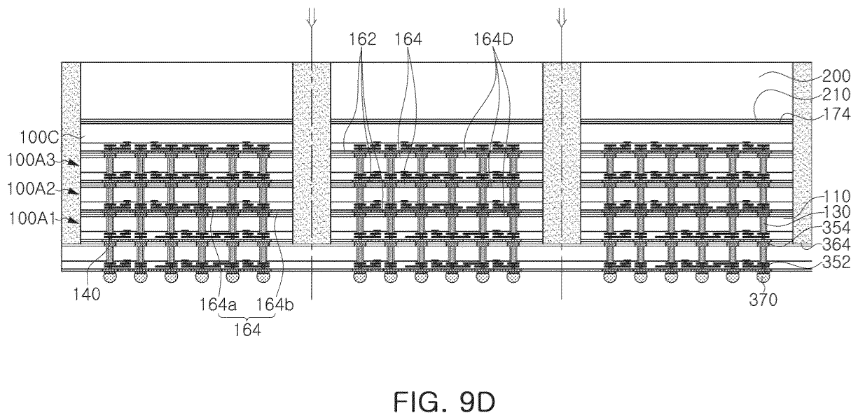

Referring to FIGS. 9A to 9D, a semiconductor package manufacturing method according to an example embodiment of the disclosure may include an operation in which a combination 162 of one support insulating layer 162a and a front insulating layer 162b of a plurality of semiconductor chips 100A1, 100A2, 100A3 and 100C is directly bonded to the other rear insulating layer 164 of the plurality of semiconductor chips 100A1, 100A2, 100A3 and 100C.

Referring to FIG. 9A, a base structure 300W having upper connection pads 354 and lower connection pads 352 is provided. In FIG. 9A, the base structure 300W is illustrated in a form for manufacturing three semiconductor packages. The base structure 300W may include an upper bonding insulating layer 364 surrounding the upper connection pads 354 on an upper surface thereof. The upper bonding insulating layer 364 may have upper surfaces that are substantially flat with upper surfaces of the upper connection pads 354. A connection bump 370 such as a solder ball may be formed on the lower connection pads 352 of the base structure 300W. Furthermore, in the present example embodiment, the base structure 300W is illustrated in a form in which a logic chip or a memory chip for electrically connecting the upper connection pads 354 and the lower connection pads 352 is implemented. But, in an embodiment, the base structure 300W may be an interposer having an internal circuit.

Referring to FIG. 9B, individualized semiconductor chips 100A1 are disposed on a base structure 300W. A semiconductor chip 100A1 may be a semiconductor chip obtained in the operation illustrated in FIG. 5G. The present stacking process may be pre-bonded by applying a predetermined pressure using a bonding tool BT. Specifically, a plurality of front pads 152 of the first semiconductor chips 100A1 are directly pre-bonded to upper connection pads 354 of a base structure 300, respectively, and similarly thereto, a front insulating layer 162 of the semiconductor chips 100A1 may be directly pre-bonded to an upper bonding insulating layer 364 of a base structure 300.

Referring to FIG. 9C, additional semiconductor chips 100A2 and 100A3 may be sequentially stacked, and a semiconductor chip 100C is disposed on an uppermost semiconductor chips 100A3. A plurality of semiconductor chips 100A2, 100A3 and 100C may be pre-bonded onto the other semiconductor chips 100A1, 100A2 and 100A3 disposed below the plurality of semiconductor chips 100A2, 100A3 and 100C. Specifically, a plurality of front pads 152 and a front insulating layer 162 of each of the semiconductor chips 100A2, 100A3 and 100C may be directly pre-bonded to each of a plurality of rear pads 154 and a rear insulating layer 164 of the semiconductor chips 100A1, 100A2 and 100A3 stacked immediately before. Then, an annealing process may be performed, and the front insulating layer 162 and the rear insulating layer 164 may be directly bonded, and the plurality of front pads 152 and the plurality of rear pads 154 may be directly bonded to each other. Then, the upper dummy chip 200 may be disposed on a rear surface (upper surface) of the semiconductor chip 100C, and a rear surface (upper surface) of the upper dummy chip 200 may be polished.

Referring to FIG. 9D, the semiconductor package illustrated in FIG. 9C may be cut in a vertical direction. Accordingly, a plurality of semiconductor packages may be formed. In an embodiment, the rear surface (upper surface) of the upper dummy chip 200 may include an identification mark or provide a space for arranging a heat sink.

As set forth above, the semiconductor package according to an example embodiment of the disclosure may improve electrical characteristics and/or reliability of a front surface of a semiconductor chip. For example, since the semiconductor package may reduce the effect of burrs caused by a dicing process of a semiconductor wafer on the flatness of a front surface of a semiconductor chip, it may be possible to improve the electrical properties of the front surface of the semiconductor chip (e.g., electrical path integration, electrical short prevention performance, signal integrity) and/or reliability (e.g., flatness of a surface, structural stability of a layer, delamination prevention performance).

The disclosure is not limited to the above-described embodiments and the accompanying drawings but is defined by the appended claims. Therefore, those of ordinary skill in the art may make various replacements, modifications, or changes without departing from the scope of the disclosure defined by the appended claims, and these replacements, modifications, or changes should be construed as being included in the scope of the disclosure.

What is claimed is:

1. A semiconductor package comprising a plurality of semiconductor chips each comprising a front insulating layer and a rear insulating layer,
wherein the plurality of semiconductor chips are bonded to each other through a first direct bonding between the front insulating layer and the rear insulating layer,
wherein at least one of the plurality of semiconductor chips comprises:
a device layer comprises a wiring structure,
a semiconductor substrate above the device layer,
a plurality of front pads electrically connected to the wiring structure in front of the device layer, and
the front insulating layer surrounding the plurality of front pads in front of the device layer, and
wherein the front insulating layer comprises a burr buried in an edge of a front surface of the front insulating layer.

2. The semiconductor package of claim 1, wherein the burr is disposed to overlap a portion of the front insulating layer in a front-rear direction, and
wherein a side surface of the burr is more recessed than a side surface of a portion of the front insulating layer overlapping the burr in the front-rear direction.

3. The semiconductor package of claim 1, wherein the burr comprises at least one of an insulating material in the device layer and a metallic material in the wiring structure.

4. The semiconductor package of claim 1, wherein the burr comprises an insulating material different from a material of the front insulating layer.

5. The semiconductor package of claim 4, wherein the front insulating layer comprises at least one of SiN, SiCN, and tetraethyloxysilane (TEOS), and
wherein the burr comprises SiO₂.

6. The semiconductor package of claim 1, wherein the burr comprises a metallic material different from a metallic material of the plurality of front pads.

7. The semiconductor package of claim 6, wherein the plurality of front pads comprises copper or a copper alloy, and
wherein the burr comprises aluminum or an aluminum alloy.

8. The semiconductor package of claim 1, further comprising:
a support insulating layer between the device layer and the front insulating layer; and
a conductive pattern surrounded by the support insulating layer,
wherein the wiring structure comprises at least one of a wiring layer and a wiring via, and
wherein a thickness of the conductive pattern is greater than a thickness of the at least one of the wiring layer or the wiring via.

9. The semiconductor package of claim 8, wherein at least one of the plurality of semiconductor chips comprises:
a through-via penetrating through the semiconductor substrate;
the rear insulating layer on a rear surface of the semiconductor substrate; and
a plurality of rear pads surrounded by the rear insulating layer and electrically connected to the through-via,
wherein the plurality of semiconductor chips are electrically connected to each other through a second direct bonding between the plurality of front pads and the plurality of rear pads.

10. The semiconductor package of claim 9, wherein each of the front insulating layer, the support insulating layer, and the rear insulating layer comprises at least one of SiO₂, SiN, SiCN, and tetraethyloxysilane (TEOS),
wherein the plurality of front pads comprise copper or a copper alloy, and
wherein the conductive pattern comprises at least one of copper, the copper alloy, aluminum, and an aluminum alloy.

11. The semiconductor package of claim 1, wherein the front insulating layer has a step portion in the edge of the front surface of the front insulating layer, and
wherein the burr is disposed in the step portion so as to overlap a portion of the front insulating layer in a front-rear direction.

12. The semiconductor package of claim 11, wherein a height of the step portion is greater than a width of the step portion.

13. The semiconductor package of claim 11, wherein a height of the step portion is about 2.5 μm or more, and
wherein a width of the step portion is about 5 μm or more.

14. A semiconductor package comprising:
a semiconductor chip comprising:
a front insulating layer;
a plurality of front pads surrounded by the front insulating layer;
a device layer comprising a wiring structure electrically connected to the plurality of front pads and above the front insulating layer;
a semiconductor substrate above the device layer;
a through-via penetrating through the semiconductor substrate; and
a rear insulating layer above the semiconductor substrate,
wherein the front insulating layer has a step portion formed in an edge of a front surface of the front insulating layer, and
wherein the front insulating layer comprises a burr in the step portion so as to overlap a portion of the front insulating layer in a front-rear direction.

15. The semiconductor package of claim 14, wherein the burr comprises at least one of an insulating material in the device layer and a metallic material in the wiring structure.

16. The semiconductor package of claim 14, wherein a height of the step portion is greater than a width of the step portion,
wherein the height of the step portion is about 2.5 μm or more, and
wherein the width of the step portion is about 5 μm or more.

17. A semiconductor package manufacturing method comprising:
forming a mask layer in front of a wafer comprising a semiconductor substrate, a device layer in front of the semiconductor substrate, and a front insulating layer in front of the device layer;
forming a step portion in an edge of a front surface of the front insulating layer by removing a portion of the front insulating layer that does not overlap the mask layer in a front-rear direction along a scribe lane region of the wafer;
removing a portion of the device layer and another portion of the front insulating layer having a width narrower than a width of a portion of the front insulating layer along the scribe lane region;
removing a portion of the semiconductor substrate along the scribe lane region; and
removing the mask layer.

18. The semiconductor package manufacturing method of claim 17, wherein in the removing the portion of the device layer and the another portion of the front insulating layer, a femtosecond laser grooving process is used.

19. The semiconductor package manufacturing method of claim 18, wherein in the forming the step portion, a plasma process is used.

20. The semiconductor package manufacturing method of claim 17, wherein a height of the step portion is about 2.5 μm or more, and
wherein a half of a difference between a width of a portion of the front insulating layer and a width of another portion of the front insulating layer is shorter than the height of the step portion and is about 5 μm or more.
